(19) United States
(12) Patent Application Publication
(10) Pub. No.: US 2013/0213576 A1
(43) Pub. Date: Aug. 22, 2013

(54) PLASMA PROCESSES AT ATMOSPHERIC PRESSURE

(71) Applicants: Roland Gesche, Seligenstadt (DE); Horia-Eugen Porteanu, Berlin (DE); Silvio Kühn, Wandlitz (DE)

(72) Inventors: Roland Gesche, Seligenstadt (DE); Horia-Eugen Porteanu, Berlin (DE); Silvio Kühn, Wandlitz (DE)

(73) Assignee: Forschungsverbund Berlin E.V., Berlin (DE)

(21) Appl. No.: 13/817,537

(22) PCT Filed: Aug. 16, 2011
(86) PCT No.: PCT/EP2011/064075

§ 371 Date: Apr. 24, 2013

(30) Foreign Application Priority Data
Aug. 16, 2010 (DE) 10 2010 039 365.7

(51) Int. Cl. H01J 37/32; H05H 1/42

(52) U.S. Cl. CPC H01J 37/32; H05H 1/42
USPC 156/345.44; 118/723 E

(57) ABSTRACT

The invention relates to an apparatus for the treatment of surfaces of a substrate by means of plasma. Said apparatus comprises a plasma source designed to generate plasma and to eject it into a plasma space with a longitudinal plasma extent, said extent extending along a main motion component of the plasma, an at least partially conductive first holding apparatus designed to hold a first workpiece, and a voltage source connected to the first holding apparatus, said voltage source being designed to generate a first acceleration voltage and to apply it to the first holding apparatus. The first holding apparatus is arranged and designed relative to the plasma source in such a manner that it places the first workpiece in such a manner that the plasma reaches the first workpiece when the first acceleration voltage is applied.

### TECHNICAL FIELD

The invention relates to an apparatus for the treatment of surfaces of a substrate by means of plasma, said apparatus being capable of operating at atmospheric pressure or at vacuum close to atmospheric pressure.

### STATE OF THE ART

Plasma enhanced methods are widely used for surface treatment, wherein reactive ion etching, sputtering and reactive sputtering are the most important methods. Reactive ion etching is aimed at etching structures into a workpiece, whereas sputtering is aimed at depositing thin layers onto the workpiece.

According to the present industrial methods, a gas discharge (plasma) is generated in a vacuum chamber in a low-pressure range between approximately 0.01 Pa and 10 Pa, e.g., by a direct voltage or a high-frequency alternating voltage, wherein the geometrical extent of the plasma corresponds to that of the vacuum chamber, in which the workpiece to be treated (usually referred to as a substrate) is placed. Since substrates in a range from few millimeters to several meters are to be industrially treated by means of plasma processes, it is necessary to generate appropriately large plasmas in a stable manner. This requires operating in the above-mentioned pressure range. Otherwise, the plasma will collapse or filament and thus become unsuitable for surface treatment. Operating at low pressures causes, on the one hand, a high vacuum generation effort and, on the other hand, a reduced throughput of the manufacturing plant on account of the time required therefor before the actual treatment of the substrate can start.

Therefore, there is a need for plasma enhanced methods that can be executed at atmospheric pressure or at least at pressures that are close to atmospheric pressure.

### DISCLOSURE OF THE INVENTION

Therefore, according to the invention, an apparatus for the treatment of surfaces of a substrate by means of plasma is introduced, said apparatus being capable of operating at atmospheric pressure or at pressures that are close to atmospheric pressure, wherein “a pressure close to atmospheric pressure” is a pressure of between one tenth of standard atmospheric pressure and standard atmospheric pressure.

The apparatus comprises a plasma source, an at least partially conductive first holding apparatus, and a voltage source, which is connected to the first holding apparatus. The plasma source is designed to generate plasma and to eject it into a plasma space with a longitudinal plasma extent, said extent extending along a main motion component of the plasma. The first holding apparatus is designed to hold a first workpiece. The voltage source is designed to generate a first acceleration voltage and to apply it to the first holding apparatus, wherein the first holding apparatus is arranged and designed relative to the plasma source in such a manner that it places the first workpiece in such a manner that the plasma reaches the first workpiece when the first acceleration voltage is applied.

The invention is based on the use of a plasma source instead of the ignition of plasma in a vacuum chamber. A plasma source continuously generates plasma and ejects it in a similar manner as a gas burner on account of the supply of gas to be ionized. It is also possible to use a pulsed or modulated plasma source. Nevertheless, such a plasma source ejects plasma during the whole operating time so that it is suitable for use within the scope of the invention. The plasma generated by the plasma source in this manner recombines after a certain period of time so that a plasma space is formed whose extent depends on various parameters, such as the pressure and the gas or gas mixture used, wherein the “plasma space” is the space in which free charge carriers are present.

At pressures that are close to atmospheric pressure, the longitudinal plasma extent of the plasma space is usually in the millimeter range. Although it is impossible to generate plasma in a stable manner at such comparatively high pressures, ions for surface treatment are available at any time on account of the continuous generation of plasma by the plasma source.

The invention includes the finding that the free charge carriers generated by the plasma source (primary plasma) can generate additional plasma (secondary plasma). By inventively applying a first acceleration voltage to the first holding apparatus (electrode) by the voltage source, the free charge carriers of the primary plasma are accelerated in the electric field, wherein they ionize further gas atoms on account of collision processes. On account of the plasma flowing from the plasma source, the ignition voltage required therefor is considerably lower than expected for a given pressure.

This surprising effect allows the provision of a sufficiently large particle stream for surface treatment processes that previously were possible in vacuum only.

The proper operation of the apparatus can only be ensured if the plasma can reach the first workpiece so that ions from the plasma can impinge on the first workpiece. Since the plasma expands after the applying of the first acceleration voltage, a number of experimental set-ups might be necessary in order to find the optimal arrangement for a given workpiece.

The apparatus may comprise a vacuum chamber, in which the plasma source and the first holding apparatus are arranged and which is designed to generate a vacuum chamber pressure of between one tenth of standard atmospheric pressure and standard atmospheric pressure. Although the invention allows the execution of plasma processes at higher pressures, the quality and efficiency of the processes can be improved by executing said processes at a reduced pressure. However, the invention allows the use of pressures that are higher than the pressures required for known methods.

The first acceleration voltage may be a direct voltage whose polarity sign is selected such that the potential of the first holding apparatus is negative relative to the potential of the plasma, wherein the first acceleration voltage is preferably in a range between −100 and −1000 V. Alternatively, the first acceleration voltage may be an alternating voltage having a frequency of less than 100 MHz.

The apparatus may have a second holding apparatus for a second workpiece, wherein the first workpiece is a target and the second workpiece is a substrate and the apparatus is designed to extract material from the target and to transfer it to the substrate.

This particularly preferred embodiment of the invention may be used for sputtering processes, which are aimed at extracting material from a target by means of ion bombardment and depositing it onto a substrate, i.e., onto the actual workpiece, wherein the target is consumed during a large number of process cycles and is therefore replaced at intervals. On the other hand, embodiments without a second holding apparatus may be used for reactive ion etching, where the target is the actual workpiece and is etched in the desired manner by means of ion bombardment.

In the apparatus designed for sputtering, the second holding apparatus may be at least partially conductive and may be connected to the voltage source, wherein the voltage source is designed to generate a second acceleration voltage and to apply it to the second holding apparatus. On account of the comparatively high pressure according to the invention, the density of the gas that is between the target and the substrate is correspondingly high so that the particles extracted from the target are slowed down by the gas on their way toward the substrate to a relatively large extent. With particular materials, the reduced velocity of the target particles might unfavorably cause the particles to adhere to the substrate only poorly. Therefore, a second acceleration voltage may be useful. Said second acceleration voltage is applied to the substrate via the second holding apparatus provided that the substrate itself is conductive. Otherwise, the second holding apparatus itself functions as an electrode. Said second acceleration voltage accelerates the ions in the plasma toward the substrate and indirectly accelerates the target particles on account of further collisions between the ions and the target particles. The second acceleration voltage is preferably in a range between −10 and −100 V.

The first holding apparatus may be designed to hold a cylindrical target, wherein the first holding apparatus is preferably arranged relative to the plasma source in such a manner that the plasma flows through the cylindrical target through a hole arranged along the cylinder axis of the cylindrical target, wherein the cylindrical target may be arranged directly at the plasma source so that the first holding apparatus is integrated in the plasma source.

An advantage of such an arrangement with a cylindrical target consists in the fact that the plasma flows through the target and its flow velocity encourages the transfer of the target particles to the substrate. Moreover, the substrate may be arranged directly in the direction of motion of the plasma.

The plasma source may have a cylindrical resonator, wherein the target is preferably wire-shaped and arranged, or can be arranged, along the cylinder axis of the resonator, wherein the target may function as an inductor and be a part of an oscillating circuit that comprises the target and the resonator as an LC component. The high-frequency oscillation generated by the oscillating circuit generates the plasma, which flows out through a hole in the resonator, said hole being arranged near the target tip, preferably in the resonator axis.

Preferably, the apparatus has a frequency determination unit connected to the first holding apparatus, said frequency determination unit being designed to determine the frequency of a signal that is present at the cylindrical resonator, to compare the determined frequency with a predetermined or predeterminable nominal frequency, and to output a result signal indicating a result of the comparison, wherein the first holding apparatus is designed to displace the wire-shaped target along the cylinder axis of the resonator, wherein a displacement direction of the displacement depends on the result signal.

The resonant frequency of the arrangement made up of the resonator and the wire-shaped target depends on the length of the wire-shaped target within the resonator and can therefore be influenced by displacing the target within the resonator, which also means, by implication, that the frequency of the oscillation indicates the distance between the tip of the wire-shaped target and the hole in the resonator. The present embodiment makes use of this finding in a control loop by displacing the wire-shaped target, which is continuously eroded at its tip by the action of the plasma, so that the tip of the target can be kept at a desired distance from the hole in the resonator at any time, said displacement being dependent on the determined frequency.

The second holding apparatus may be designed to move along a first direction in response to a first control signal and to move along a second direction in response to a second control signal, said second direction crossing the first direction, wherein a second holding apparatus designed to move a substrate correspondingly is considered to be equivalent to the second holding apparatus described first. The apparatus has a control unit designed to receive geometrical data and to move the second holding apparatus, by outputting first and second control signals derived from the geometrical data, relative to the first holding apparatus in such a manner that the material extracted from the target is transferred to a region of the substrate surface that is predetermined by the geometrical data.

This embodiment allows a transfer of target material to that part of the substrate which is moved through the range of action of the plasma by the second holding apparatus, thereby allowing the execution of a method that is similar to printing. For example, said method may be advantageously used for the coating of printed circuit boards by printing strip conductors directly onto the printed circuit boards. Particularly preferably, it is also possible to use plastic housings as a substrate so that the circuit of an electronic device is directly deposited onto an inner surface of the housing, which provides great potential for savings in the manufacturing of electronic devices.

Preferably, the first holding apparatus and the second holding apparatus are arranged relative to each other in such a manner that a distance between a target located in the first holding apparatus and a substrate located in the second holding apparatus is less than 3 μm. This small distance allows a reliable and accurate transfer of target material to the substrate.

The second holding apparatus may be designed to move along a third direction in response to a third control signal, wherein the third direction creates a space together with the first direction and the second direction. The apparatus has a distance determination unit designed to determine a distance between the target and the substrate. The control unit is designed to adjust the distance between the target located in the first holding apparatus and the substrate located in the second holding apparatus by outputting appropriate third control signals. This embodiment allows maintaining a constant distance from the surface of the substrate.

In principle, a target is a replaceable wearing object in sputtering processes, whereas the substrate is the workpiece to be treated. Therefore, the target and the substrate are in principle not to be regarded as elements that co-define the scope of the present invention.

### BRIEF DESCRIPTION OF THE FIGURES

In the following, the invention will be described in greater detail on the basis of figures of exemplary embodiments, wherein identical reference numerals are assigned to identical or similar objects.

FIG. 1 shows a first exemplary embodiment of the invention.

FIG. 2 shows a second exemplary embodiment of the invention, with a cylindrical target.

FIG. 3 shows a third exemplary embodiment of the invention, likewise with a cylindrical target.

FIG. 4 shows a fourth exemplary embodiment of the invention, with a wire-shaped target.

FIG. 5 shows a fifth exemplary embodiment of the invention, with a wire-shaped target arranged in a resonator.

### DETAILED DESCRIPTION OF THE FIGURES

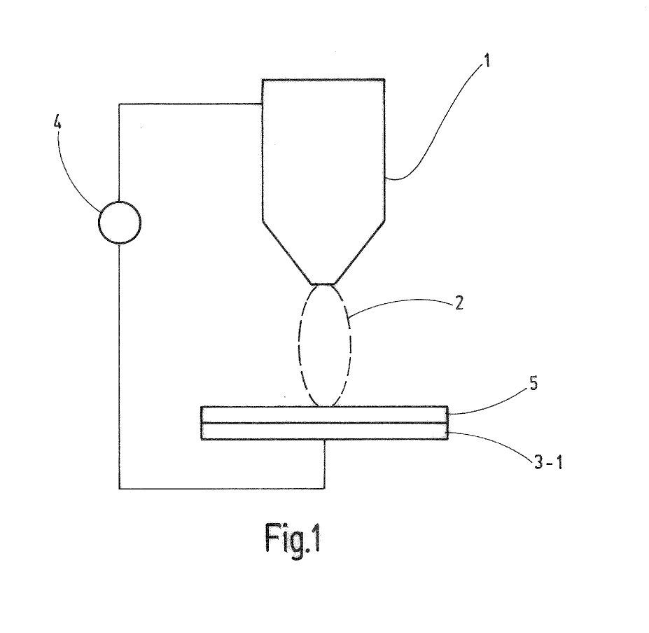

FIG. 1 shows a first exemplary embodiment of the invention. A plasma source 1 generates a plasma 2 and ejects it. In the range of action of the plasma, a workpiece 5 is arranged in a first holding apparatus 3-1. In the simplest case, said first holding apparatus 3-1 may be the bottom of a chamber, in which the plasma source 1 is arranged. The first holding apparatus 3-1 is at least partially electrically conductive and connected to a voltage source 4, which generates a potential that is negative relative to the potential of the plasma source 1 or generates an alternating voltage having a frequency in a range from some kilohertz to approximately 100 megahertz. If the workpiece 5 itself is electrically conductive, it will do if the voltage generated by the voltage source 4 reaches the workpiece 5 via a contact point between the workpiece 5 and the first holding apparatus 3-1 since the workpiece 5 itself can function in this case as an electrode for the acceleration of the ions to be extracted from the plasma 2. However, if the workpiece 5 is made of an electrically insulating material, the first holding apparatus 3-1 is preferably plane so that ions can reach the workpiece 5 along the full extent of the workpiece 5, wherein the ions follow the electric field generated by the first holding apparatus 3-1, which functions as an electrode.

The exemplary embodiment of FIG. 1 may be used for the cleaning of surfaces or for etching processes, wherein a gas mixture may be used in particular embodiments, said gas mixture containing chemical etchants aside from the plasma gas, wherein argon is the generally preferred plasma gas.

In the literature, the workpiece 5 is sometimes referred to as a target because the ions from the plasma 2 impinge on the workpiece 5 and eject particles therefrom. On the other hand, the workpiece 5 is also referred to as a substrate because the workpiece 5 is the actual object to be treated. In connection with sputtering processes, in which a surface is to be coated, the target is a material source for that material which is to be transferred to the surface of a substrate during the coating process.

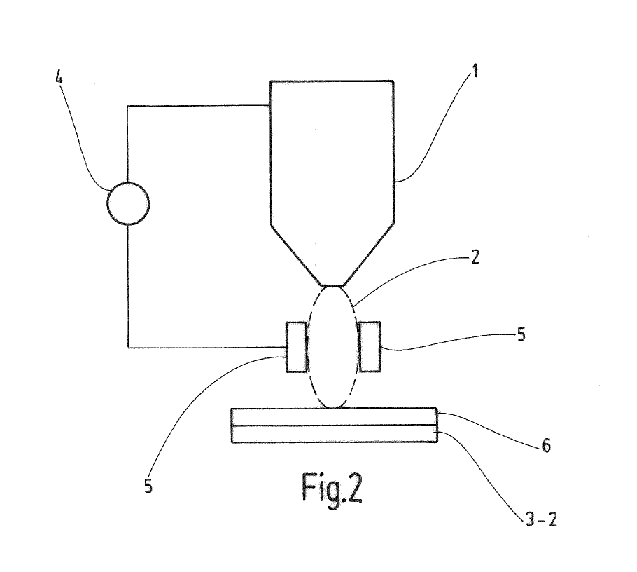

FIG. 2 shows a second exemplary embodiment of the invention, which is suitable for sputtering processes and has a cylindrical target 5. The figure shows a cross-sectional view so that the target 5, which is a hollow cylinder, is shown in the form of two rectangular portions arranged on both sides of the plasma 2. The plasma 2 can flow through the target 5 and extract particles from the target 5 by means of the ion bombardment initiated by the acceleration voltage generated by the voltage source 4. The particles from the target material reach the surface of the substrate 6 by means of the flow of gas and, optionally, by means of an additional acceleration voltage applied to the substrate 6 or to the holding apparatus 3-2 for the substrate 6. If a second acceleration voltage is used, the holding apparatus 3-2 can function as an electrode (in the same manner as the holding apparatus in FIG. 1) if the substrate 6 is non-conductive, and the substrate 6 itself can function as an electrode if the substrate 6 is conductive. In the simplest case, the second holding apparatus 3-2 may be the bottom of a chamber (as in the exemplary embodiment of FIG. 1), in which the plasma source 1 is arranged.

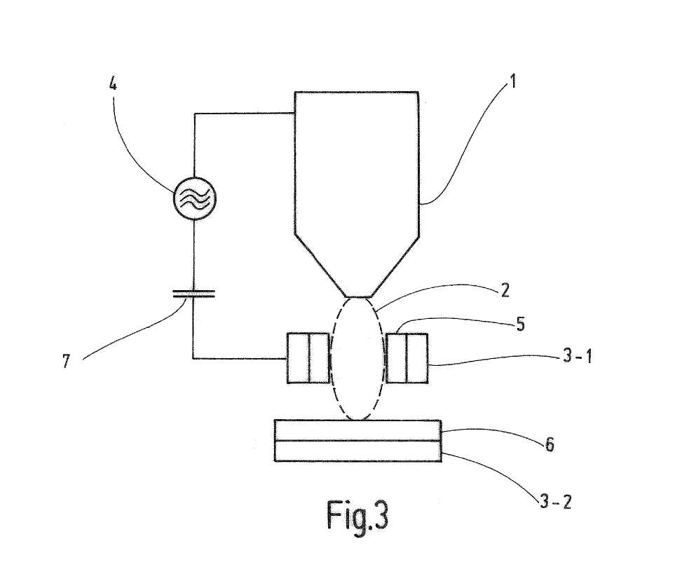

FIG. 3 shows a third exemplary embodiment of the invention. As in the exemplary embodiment of FIG. 2, there is a cylindrical target 5. The exemplary embodiment of FIG. 3 basically corresponds to that of FIG. 2 so that the features described in connection with the exemplary embodiment of FIG. 2 also apply to the exemplary embodiment of FIG. 3. However, the target 5 in the exemplary embodiment of FIG. 3 consists of a non-conductive material. For this reason, the first holding apparatus 3-1, which may be, e.g., a hollow cylinder enclosing the target 5, is at least partially made of an electrically conductive material, which can serve as an electrode for the first acceleration voltage and is connected to the voltage source 4. In this case, however, the voltage source 4 is designed to generate a high-frequency alternating voltage, preferably in a range from some kilohertz to approximately 100 megahertz. In this case, the non-conductive target 5 functions as a dielectric so that the electric field generated by the voltage source 4 can influence the plasma 2 flowing through the target 5, wherein the voltage source 4 may be coupled to the first holding apparatus 3-1 by means of an optional coupling capacitor 7.

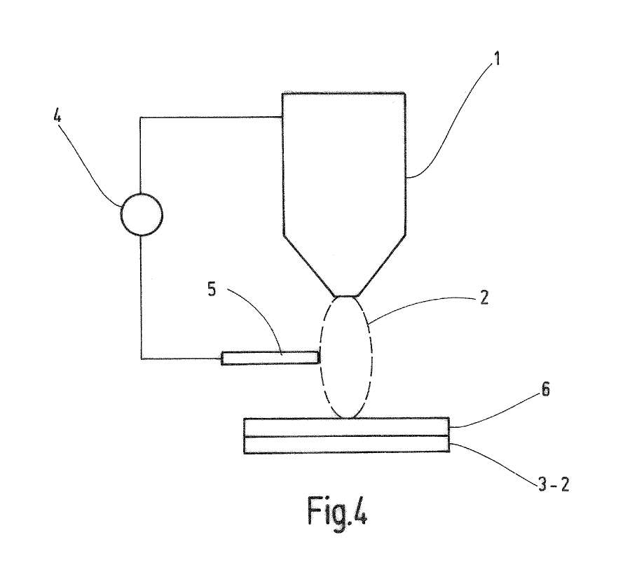

FIG. 4 shows a fourth exemplary embodiment of the invention, with a wire-shaped target 5. In this case, the target 5 is introduced into the plasma stream from the side, wherein the target material is mainly eroded at the tip of the wire-shaped target 5, said tip being located in the plasma 2. Therefore, the first holding apparatus 3-1 (not shown) is preferably designed to feed the wire-shaped target 5 into the plasma by continuously displacing the wire-shaped target 5 along the longitudinal axis thereof so that the tip of the target 5 is within the range of action of the plasma 2 at any time.

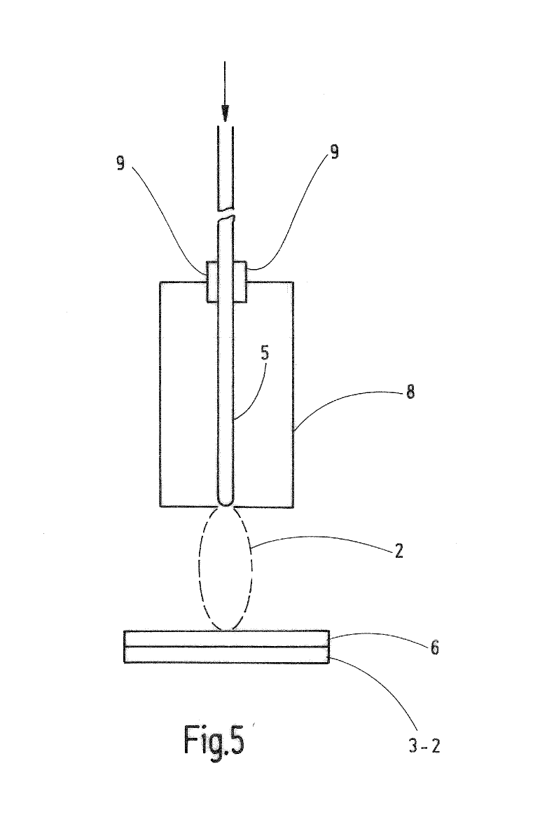

FIG. 5 shows a fifth exemplary embodiment of the invention, with a wire-shaped target 5 arranged in a resonator 8, wherein the resonator 8 is a central component of the plasma source and forms, together with the wire-shaped target 5, an oscillating LC circuit, which can be externally stimulated by an active component. The thereby generated high-frequency oscillation initiates a gas discharge in a gas conducted through the resonator so that the plasma 2 escapes through a hole in a front of the resonator. The gas discharge is initiated between the tip of the wire-shaped target 5 and the edge of the hole because the strongest electric field exists there.

The wire-shaped target 5 functions as a dipole in the arrangement and co-determines the resonant frequency of the arrangement. Therefore, the resonant frequency can be influenced by displacing the target 5 along the resonator axis, which also means that the resonant frequency of the oscillating circuit of the plasma source indicates the position of the tip of the wire-shaped target 5 so that it is possible to set up a control loop in which the first holding apparatus (not shown here) continuously advances the target 5 (which is consumed at its tip) so that, on the one hand, the generation of the plasma 2 is not interrupted and, on the other hand, enough target material for the sputtering process is available at any time. In order to ensure the transport of the wire-shaped target 5, a leadthrough 9 may be provided in the back wall of the resonator 8, which leadthrough 9 seals the resonator as gas-imperviously as possible but does not prevent the wire-shaped target 5 from being displaced.

If one wants to use a target made of a non-conductive material, the dipole may also be realized in the form of a waveguide. In the interior of the waveguide, the wire-shaped target is guided to the tip of the waveguide.

The exemplary embodiments of FIGS. 2 to 5 may be used, in a similar manner as a print head, for a targeted coating of selected regions of the substrate, which provides a wide variety of possible applications. For example, strip conductors for electric circuits may be printed directly onto a printed circuit board if an electrically conductive target material is used. Correspondingly, the exemplary embodiment of FIG. 1 may be used for the accurate etching or cleaning of surfaces. The invention allows the use of plasma processes at pressures that are higher than the usual pressures (up to atmospheric pressure), whereby production speed is increased and set-up costs are reduced.

1. An apparatus for the exactly localized treatment of surfaces of a substrate by means of plasma, said apparatus comprising a plasma source designed to generate plasma and to eject it into a plasma space with a longitudinal plasma extent, said extent extending along a main motion component of the plasma; an at least partially conductive first holding apparatus designed to hold a first workpiece; and a voltage source connected to the first holding apparatus, said voltage source being designed to generate a first acceleration voltage and to apply it to the first holding apparatus, wherein the first holding apparatus is arranged and designed relative to the plasma source in such a manner that it places the first workpiece in such a manner that the plasma reaches the first workpiece when the first acceleration voltage is applied.

2. The apparatus according to claim 1 having a vacuum chamber, in which vacuum chamber the plasma source and the first holding apparatus are arranged and which vacuum chamber is designed to generate a vacuum chamber pressure of between one tenth of standard atmospheric pressure and standard atmospheric pressure.

3. The apparatus according to claim 1, in which the first acceleration voltage is a direct voltage whose polarity sign is selected such that the potential of the first holding apparatus is negative relative to the potential of the plasma.

4. The apparatus according to claim 3, in which the first acceleration voltage is in a range between −100 and −1000 V.

5. The apparatus according to claim 1, in which the first acceleration voltage is an alternating voltage having a frequency of less than 100 MHz.

6. The apparatus according to claim 1 having a second holding apparatus for a second workpiece, wherein the first workpiece is a target and the second workpiece is a substrate and the apparatus is designed to extract material from the target and to transfer it to the substrate.

7. The apparatus according to claim 6, in which the second holding apparatus is at least partially conductive and is connected to the voltage source, wherein the voltage source is designed to generate a second acceleration voltage, preferably a second acceleration voltage in a range between −10 and −100 V, and to apply it to the second holding apparatus.

8. The apparatus according to claim 6, in which the first holding apparatus is designed to hold a cylindrical target and is arranged relative to the plasma source in such a manner that the plasma flows through the cylindrical target through a hole arranged along the cylinder axis of the cylindrical target.

9. The apparatus according to claim 6, in which the plasma source has a cylindrical resonator, and the target is wire-shaped and is arranged or can be arranged along the cylinder axis of the resonator.

10. The apparatus according to claim 9 having a frequency determination unit connected to the first holding apparatus, said frequency determination unit being designed to determine the frequency of a signal that is present at the cylindrical resonator, to compare the determined frequency with a predetermined or predeterminable nominal frequency, and to output a result signal indicating a result of the comparison, wherein the first holding apparatus is designed to displace the wire-shaped target along the cylinder axis of the resonator, wherein a displacement direction of the displacement depends on the result signal.

11. The apparatus according to claim 8, in which the second holding apparatus is designed to move along a first direction in response to a first control signal and to move along a second direction in response to a second control signal, said second direction crossing the first direction, wherein the apparatus has a control unit designed to receive geometrical data and to move the second holding apparatus, by outputting first and second control signals derived from the geometrical data, relative to the first holding apparatus in such a manner that the material extracted from the target is transferred to a region of the substrate surface that is predetermined by the geometrical data.

12. The apparatus according to claim 6, in which the first holding apparatus and the second holding apparatus are arranged relative to each other in such a manner that a distance between a target located in the first holding apparatus and a substrate located in the second holding apparatus is less than 3 μm.

13. The apparatus according to claim 11, in which the second holding apparatus is designed to move along a third direction in response to a third control signal, wherein the third direction creates a space together with the first direction and the second direction; and with a distance determination unit designed to determine a distance between the target and the substrate, wherein the control unit is designed to adjust the distance between the target located in the first holding apparatus and the substrate located in the second holding apparatus by outputting appropriate third control signals.

14-15. (canceled)
